(19) United States
(12) Patent Application Publication
(10) Pub. No.: US 2009/0309768 A1
(43) Pub. Date: Dec. 17, 2009

(54) MODULE, USER INTERFACE, DEVICE AND METHOD FOR HANDLING ACCIDENTAL KEY PRESSES

(75) Inventor: Pekka Juhana Pihlaja, Helsinki (FI)

Correspondence Address: Perman & Green, LLP, 99 Hawley Lane, Stratford, CT, 06614, US

(73) Assignee: NOKIA CORPORATION, Espoo (FI)

(21) Appl. No.: 12/137,829

(22) Filed: Jun. 12, 2008

(51) Int. Cl. H03K 17/94

(52) U.S. Cl. 341/24

(57) ABSTRACT

A module for avoiding accidental key presses configured to detect a key press on a first key and to temporarily deactivate a second key being adjacent to the first key.

### FIELD

The present application relates to a device and a method for providing correct input, and in particular to a module, a user interface, a device and a method for handling accidental key presses.

### BACKGROUND

More and more electronic devices such as mobile phones, MP3 players, Personal Digital Assistants (PDAs) are becoming smaller and smaller while having more and more information stored and/or accessible through them.

The environments in which these devices are used are also becoming more and more hectic with higher demands on fast access and multitasking, and not only in a professional environment but also in private and social environments. For example a user should be able to read a book, while holding a grocery bag in a rattling subway train and still be able to access the information stored in the device for the device to live up to the many requirements posed upon it by a user buying and using the device.

A consequence of the requirements for small devices paired with the requirement for easy access is that the space designated for keypads and keyboards become smaller and smaller resulting in smaller and smaller keys. This leads to an increased risk of accidentally pressing on more than one key at once thus giving conflicting signals to the device or causing additional unwanted input which corrupts a text that is being input.

Some prior art solutions for overcoming this problem have been proposed.

U.S. Pat. No. 7,289,043 discloses a portable telephone that has a key operation unit in which a plurality of small keys is arranged close to each other. A user sometimes depresses a plurality of keys at the same time. The portable telephone stores data regarding frequency of key determination made by the user in the past when the plurality of keys was depressed at the same time, with regard to a combination of these keys. When the plurality of keys is depressed at the same time, a key which has been most frequently determined is selected, and a number or the like corresponding to the key is displayed. Further, once the key is determined, data regarding the frequency of determination of the key is updated.

A disadvantage with this solution is that it requires a register to be kept and maintained containing data regarding the pressing frequency for each key and it also requires comparison software for determining which key should be taken as being the correct key. This requires additional computational and memory resources and thus leads to a slower operation and an increased cost for a device.

European Patent EP 1,185,921 discloses a method of correcting an input to a device, which a user interacts with by a series of touch actions, including the step of detecting each touch action, measuring the time interval between one or more touch actions, generating a first output in dependence on the one or more touch actions, checking the first output against a table of allowed outputs, and generating a revised output if the first output is or might be in error and if the time interval satisfies a predetermined time interval criterion.

A disadvantage with this solution is that it requires a table of allowed outputs to be kept and maintained and it also requires comparison software for determining which key should be taken as being the correct key. This requires additional computational and memory resources and thus leads to a slower operation and an increased cost for a device.

European Patent EP 1,791,051 discloses a system and a method of processing keystrokes being entered in an electronic device are provided. The method comprises: monitoring for activation of two or more keys on the device; determining whether a keystroke conflict occurs from the activation of the keys; and if a conflict has occurred, then executing further steps. The further steps include: identifying a selected key from the activated keys; generating a character associated with the selected key; and ignoring activation of any keys other than the selected key. The system comprises an electronic device with a display, a keypad and modules which perform the steps of the method as noted.

The selected key may be identified based on a dictionary match that has the same disadvantage as discussed above.

The selected key may also be identified based on the time lapsed between to key presses and this has the disadvantage that other keys are deactivated for a long time wherein no other key presses will be accepted thus slowing down the input speed possible.

The selected key may also be identified based on a highest ranking scheme similar to the one disclosed in U.S. Pat. No. 7,289,043 discussed above.

A device that provides for a quick and reliable way of differentiating between accidental and intentional key presses would be useful in modern day society, but due to the power needed to keep all the features of the device active and the size of the screen needed to display all the information at once would make this device too big to be easy to carry around.

### SUMMARY

On this background, it would be advantageous to provide a device and a method that overcomes or at least reduces the drawbacks indicated above by providing a module, a user interface, a device and a method for avoiding accidental key presses configured to ignore or deactivate neighboring or adjacent keys.

The disclosed embodiments provide a module for avoiding accidental key presses configured to detect a key press on a first key and to temporarily deactivate a second key being adjacent to said first key.

By taking advantage of lateral inhibition the adjacent or neighboring keys are deactivated or ignored and thus can not produce or generate any data input by mistake or accident.

A major advantage with such a module is that it can be implemented easily without requiring computational resources or memory resources for storing and maintaining tables, and dictionaries.

Another advantage of only deactivating the adjacent or neighboring keys is that other keys can still be used for input and also to be used for combined input.

Yet another advantage is that a user may still maintain a high input speed as remotely located keys where there is no risk of accidentally pressing the wrong key can still be input at a very high speed.

In one embodiment the module is further configured to generate key input data corresponding to said first key.

In one embodiment the module is further configured to detect a release of said first key and to reactivate said second key upon said release.

This enables a device incorporating such a module to receive fast and correct input as no timeout periods are measured. Also, as no timeout periods are used the input can be performed faster as no unnecessary waiting for timeout periods are induced when trying to input the same characters or characters adjacent each other.

In one embodiment the module is further configured to detect whether a time period since the detected key press has lapsed or not and reactivate said second key as said time period has lapsed.

This avoids sideways movements to result in accidental key presses.

In one embodiment the module is further configured to detect a release of said second key and to reactivate said second key upon said release.

This avoids data to be accidentally generated from a second key that is kept depressed while the first key is released.

In one embodiment the module comprises logic circuitry for deactivating or reactivating said second key. This allows for a fast and computationally undemanding way of controlling the input.

The aspects of the disclosed embodiments are also directed to providing a user interface incorporating or configured to incorporate a module according to above.

In one embodiment the user interface is further configured to execute a first and a second application, wherein said user interface is configured to detect a key press on a first key and to temporarily deactivate a second key being adjacent to said first key when executing said first application.

In one embodiment the first application comprises an input field and wherein said user interface is configured to detect a key press on a first key and to temporarily deactivate a second key being adjacent to said first key when said input field is active.

The aspects of the disclosed embodiments are also directed to providing a device incorporating or configured to incorporate a module according to above.

The aspects of the disclosed embodiments are also directed to providing a device incorporating or configured to incorporate a user interface according to above.

In one embodiment the device is a mobile phone.

In one embodiment the device is a mobile communications terminal.

In one embodiment the device is a personal digital assistant (PDA).

In one embodiment the device is a laptop computer.

In one embodiment the device is a notebook computer.

In one embodiment the device is a palmtop computer.

In one embodiment the device is a camera, video or photography.

In one embodiment the device is an external keyboard.

In one embodiment the device is a game console.

Such devices and user interface has the same advantages as has been discussed above.

The aspects of the disclosed embodiments are also directed to providing a computer readable medium including at least computer program code for controlling a user interface comprising a keypad, said computer readable medium comprising software code for detecting a key press of a first key and software code for deactivating a second key.

Such a computer readable medium and the embodiments below have the same advantages as has been discussed above.

In one embodiment the computer readable medium further comprises software code for generating key input data corresponding to said first key.

In one embodiment the computer readable medium further comprises software code for detecting a release of said first key and for reactivating said second key upon said release.

In one embodiment the computer readable medium further comprises software code for detecting whether a time period since the detected key press has lapsed or not and reactivating said second key as said time period has lapsed.

In one embodiment the computer readable medium further comprises software code for detecting a release of said second key and to for reactivating said second key upon said release.

The aspects of the disclosed embodiments are also directed to providing a device incorporating and implementing a computer readable medium according to above.

The aspects of the disclosed embodiments are also directed to providing a device for avoiding accidental key presses comprising means for detecting a key press on a first key and means for temporarily deactivating a second key being adjacent to said first key.

Such a device and the embodiments below have the same advantages as has been discussed above.

In one embodiment the device further comprises means for generating key input data corresponding to said first key.

In one embodiment the device further comprises means for means for detecting a release of said first key and means for reactivating said second key upon said release.

The aspects of the disclosed embodiments are also directed to providing a method for avoiding accidental key presses comprising detecting a key press on a first key and temporarily deactivating a second key being adjacent to said first key.

Such a method and the embodiments described below have the same advantages as has been discussed above.

In one embodiment the method further comprises generating key input data corresponding to said first key.

In one embodiment the method further comprises detecting a release of said first key and reactivating said second key upon said release.

In one embodiment the method further comprises detecting whether a time period since the detected key press has lapsed or not and reactivating said second key as said time period has lapsed.

In one embodiment the method further comprises detecting a release of said second key and reactivating said second key upon said release.

The aspects of the disclosed embodiments are also directed to providing a device incorporating and implementing a method according to above.

Further objects, features, advantages and properties of device, method and computer readable medium according to the present application will become apparent from the detailed description.

### BRIEF DESCRIPTION OF THE DRAWINGS

In the following detailed portion of the present description, the teachings of the present application will be explained in more detail with reference to the example embodiments shown in the drawings, in which:

FIG. 1 is an overview of a telecommunications system in which a device according to the present application is used according to an embodiment,

FIG. 2 is a plane front view of a device according to an embodiment,

FIG. 3 is a block diagram illustrating the general architecture of a device of FIG. 2 in accordance with the present application,

FIGS. 4A and B are flow charts each describing a method according to an embodiment,

FIGS. 5, a, b, c and d are cut out views of a device according to an embodiment, and

FIGS. 6A and B are flow charts each describing a method according to an embodiment.

### DETAILED DESCRIPTION

In the following detailed description, the device, the method and the software product according to the teachings for this application in the form of a cellular/mobile phone will be described by the embodiments. It should be noted that although only a mobile phone is described the teachings of this application can also be used in any electronic device such as in portable electronic devices such as laptops, PDAs, mobile communication terminals, electronic books and notepads and other electronic devices offering access to information.

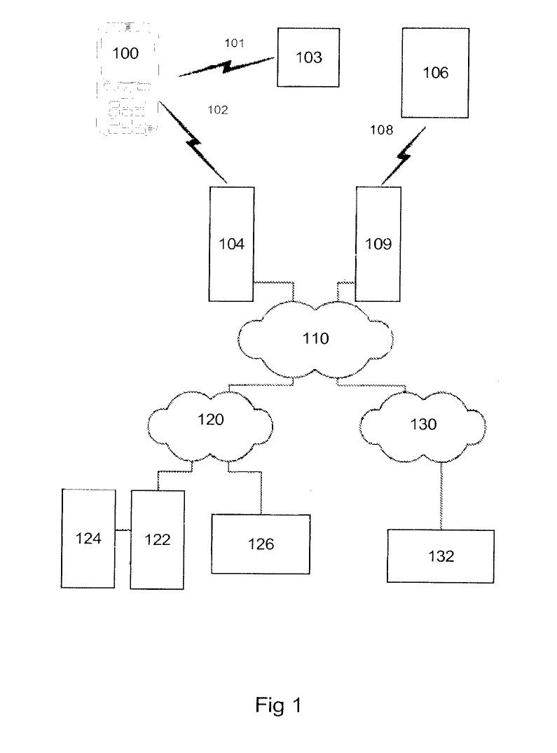

FIG. 1 illustrates an example of a cellular telecommunications system in which the teachings of the present application may be applied. In the telecommunication system of FIG. 1, various telecommunications services such as cellular voice calls, www or Wireless Application Protocol (WAP) browsing, cellular video calls, data calls, facsimile transmissions, music transmissions, still image transmissions, video transmissions, electronic message transmissions and electronic commerce may be performed between a mobile terminal 100 according to the teachings of the present application and other devices, such as another mobile terminal 106 or a stationary telephone 132. It is to be noted that for different embodiments of the mobile terminal 100 and in different situations, different ones of the telecommunications services referred to above may or may not be available; the teachings of the present application are not limited to any particular set of services in this respect.

The mobile terminals 100, 106 are connected to a mobile telecommunications network 110 through Radio Frequency, RF links 102, 108 via base stations 104, 109. The mobile telecommunications network 110 may be in compliance with any commercially available mobile telecommunications standard, such as Group Spéciale Mobile, GSM, Universal Mobile Telecommunications System, UMTS, Digital Advanced Mobile Phone system, D-AMPS, The code division multiple access standards CDMA and CDMA2000, Freedom Of Mobile Access, FOMA, and Time Division-Synchronous Code Division Multiple Access, TD-SCDMA.

The mobile telecommunications network 110 is operatively connected to a wide area network 120, which may be Internet or a part thereof. An Internet server 122 has a data storage 124 and is connected to the wide area network 120, as is an Internet client computer 126. The server 122 may host a www/wap server capable of serving www/wap content to the mobile terminal 100.

A public switched telephone network (PSTN) 130 is connected to the mobile telecommunications network 110 in a familiar manner. Various telephone terminals, including the stationary telephone 132, are connected to the PSTN 130.

The mobile terminal 100 is also capable of communicating locally via a local link 101 to one or more local devices 103. The local link can be any type of link with a limited range, such as Bluetooth, a Universal Serial Bus (USB) link, a Wireless Universal Serial Bus (WUSB) link, an IEEE 802.11 wireless local area network link, a Radio Standard link for example an RS-232 serial link, etc. The local devices 103 can for example be various sensors that can communicate measurement values to the mobile terminal 100 over the local link 101.

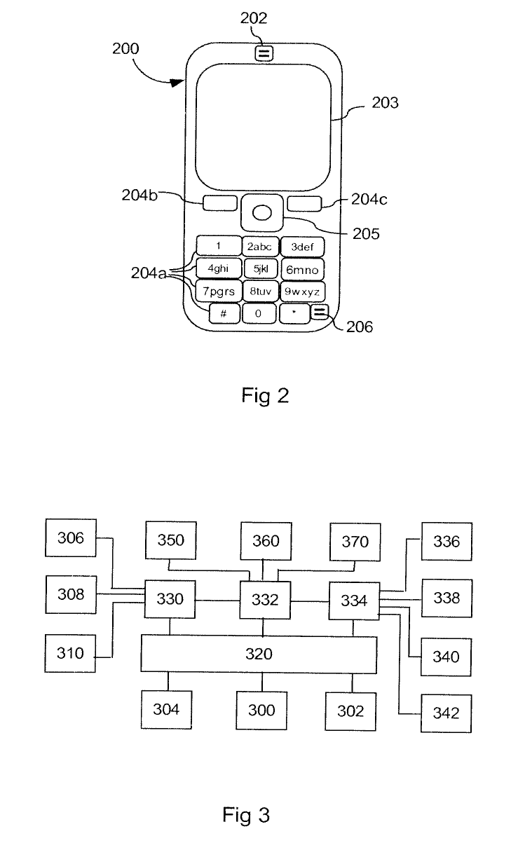

An embodiment 200 of the mobile terminal 100 is illustrated in more detail in FIG. 2. The mobile terminal 200 comprises a speaker or earphone 202, a microphone 206, a main or first display 203 and a set of keys 204 which may include a keypad 204a of common ITU-T type (alpha-numerical keypad representing characters “0”-“9”, “*” and “#”) and certain other keys such as soft keys 204b, 204c and a joystick 205 or other type of navigational input device.

The internal component, software and protocol structure of the mobile terminal 200 will now be described with reference to FIG. 3. The mobile terminal has a controller 300 which is responsible for the overall operation of the mobile terminal and may be implemented by any commercially available CPU (“Central Processing Unit”), DSP (“Digital Signal Processor”) or any other electronic programmable logic device. The controller 300 has associated electronic memory 302 such as Random Access Memory (RAM) memory, Read Only memory (ROM) memory, Electrically Erasable Programmable Read-Only Memory (EEPROM) memory, flash memory, or any combination thereof. The memory 302 is used for various purposes by the controller 300, one of them being for storing data used by and program instructions for various software in the mobile terminal. The software includes a real-time operating system 320, drivers for a man-machine interface (MMI) 334, an application handler 332 as well as various applications. The applications can include a message text editor 350, a notepad application 360, as well as various other applications 370, such as applications for voice calling, video calling, sending and receiving Short Message Service (SMS) messages, Multimedia Message Service (MMS) messages or email, web browsing, an instant messaging application, a phone book application, a calendar application, a control panel application, a camera application, one or more video games, a notepad application, etc. It should be noted that two or more of the applications listed above may be executed as the same application

The MMI 334 also includes one or more hardware controllers, which together with the MMI drivers cooperate with the first display 336/203, and the keypad 338/204 as well as various other Input/Output devices such as microphone, speaker, vibrator, ringtone generator, LED indicator, etc. As is commonly known, the user may operate the mobile terminal through the man-machine interface thus formed.

The software also includes various modules, protocol stacks, drivers, etc., which are commonly designated as 330 and which provide communication services (such as transport, network and connectivity) for an RF interface 306, and optionally a Bluetooth interface 308 and/or an IrDA interface 310 for local connectivity. The RF interface 306 comprises an internal or external antenna as well as appropriate radio circuitry for establishing and maintaining a wireless link to a base station (e.g. the link 102 and base station 104 in FIG. 1). As is well known to a man skilled in the art, the radio circuitry comprises a series of analogue and digital electronic components, together forming a radio receiver and transmitter. These components include, band pass filters, amplifiers, mixers, local oscillators, low pass filters, Analog to Digital and Digital to Analog (AD/DA) converters, etc.

The mobile terminal also has a Subscriber Identity Module (SIM) card 304 and an associated reader. As is commonly known, the SIM card 304 comprises a processor as well as local work and data memory.

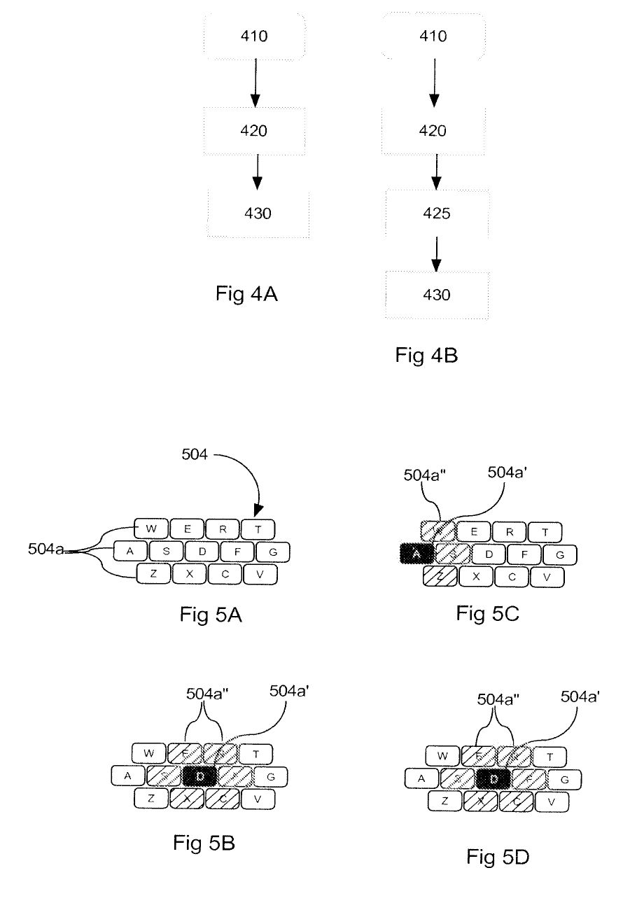

FIG. 4 shows a flow chart according to an embodiment and will be discussed with simultaneous reference to FIG. 5 which is a cut-out view of a keypad.

In FIG. 5A a portion 504 of a QWERTY-keypad is shown. Although only a QWERTY keypad is shown it should be understood that the teachings are also applicable to other keypads such as ITU-T, AZERTY, QWERTZ and other variants such as the keypad used for the Nokia Communicator™. It should also be noted that the teachings herein apply to both physical keypads as well as virtual keypads.

The keypad 504 has a plurality of keys 504a as can be seen in FIG. 5A. As a first key 504a′ is pressed in step 410 a key press is detected. In FIG. 5B the first key is marked as having inverted colors, i.e. a black key with white markings. In step 420 the adjacent keys 504a″, also referred to from now on as second keys which are marked as being shadowed with diagonal stripes, are deactivated and any press on those keys are ignored.

Thus, in the example shown in FIG. 5B any accidental press on either of the keys marked ‘E’, ‘R’, ‘S’, ‘F’, ‘X’ and ‘C’ will be ignored thus preventing a user from accidentally inputting an ‘F’ should his finger (not shown) accidentally press on the key marked ‘F’ as well as on the key marked ‘D’.

In a further step 425 key input data corresponding to the first key 504a′ is generated and in this example carrying the character ‘D’.

In a consecutive step 430 the second keys 504b″ are reactivated again and future presses on these keys will not be ignored.

In one embodiment the second keys are reactivated as the first key is released. As a user begins moving his finger or a stylus away from the keypad there is a very low risk of further accidental key presses and the adjacent keys can be reactivated again.

In one embodiment the second keys are reactivated after a short time period has lapsed from the release of the first key. This time period ensures that even sideways movements do not cause any accidental key presses.

In one embodiment the second keys 504a″ are reactivated as one of them has been released.

In one embodiment the second keys 504a″ are reactivated as all of them has been released.

In one embodiment the second keys 504a″ are reactivated as they are each released.

As only the adjacent keys or second keys 504a″ are deactivated, key input can still be received through the other keys which allows for a faster overall input speed. In FIG. 5C a remotely located key may be pressed shortly after the first key has been pressed. This remotely located key will then also be perceived as a first key 504a′ see FIG. 5C and the keys adjacent to this first key 504a′ will then be second keys 504a″ and thus deactivated. In this example the remotely located first key is marked with the character ‘A’ and input data corresponding to this character will be generated. The steps may then be repeated again for another remotely located key, in this example the character ‘D’, see FIG. 5D is again chosen to produce the word “DAD”.

As the adjacent or second keys are deactivated and any input generated by them is ignored there is no need for memory and computational expensive actions such as storing tables, comparing against such tables and making predictive text input decisions.

It is also easy to implement the deactivation and the following reactivation in hardware or in firmware as a simple circuit, such as logic circuitry in the form of integrated circuits, logic gates or the like, or program instructions ignoring input generated by the adjacent keys is required.

In one embodiment the feature of deactivating the adjacent keys is only active for applications. And in one embodiment the feature of deactivating the adjacent keys is only active for certain fields in an application.

One exemplary embodiment is a personal digital assistant where the feature of deactivating adjacent keys upon a key press is activated for a messaging application and deactivated for a voice call dialing application. This has the advantage of allowing a user to input text correctly and to input a phone number quickly where the likelihood of pressing the same or adjacent keys is very high.

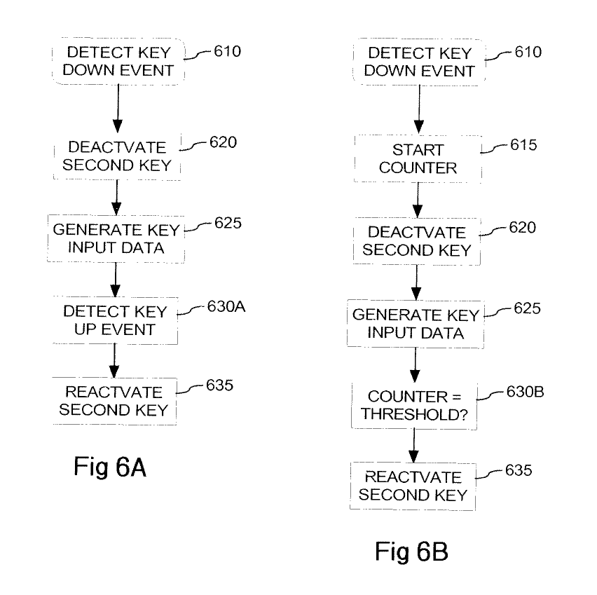

FIG. 6A shows a flowchart for a solution. In a first step 610 a key down event for a first key is detected and the adjacent or second keys are deactivated in a step 620. In a further step 625 input data corresponding to the first key is generated and as a key up event is detected in step 630A the adjacent or second keys are reactivated in step 635.

As no timeout periods are used a user is able to input text very quickly even when inputting characters f the same type or corresponding to adjacent keys.

FIG. 6B shows a flowchart for an alternative solution. In a first step 610 a key down event for a first key is detected and a counter is started in step 615. The adjacent or second keys are thereafter deactivated in a step 620 and input data corresponding to the first key is generated in a further step 625. As it is detected in step 630A that the counter has reached a threshold value the adjacent or second keys are reactivated in step 635.

This solution takes full advantage (as does the solution described with reference to FIG. 6A) of the lateral inhibition in that the keys adjacent the pressed key are deactivated to prevent accidental key presses of adjacent keys.

The various aspects of what is described above can be used alone or in various combinations. The teaching of this application may be implemented by a combination of hardware and software, but can also be implemented in hardware or software. The teaching of this application can also be embodied as computer readable code on a computer readable medium. It should be noted that the teaching of this application is not limited to the use in mobile communication terminals such as mobile phones, but can be equally well applied in Personal digital Assistants (PDAs), game consoles, MP3 players, personal organizers or any other device designed for providing information while maintaining low power consumption.

The teaching of the present application has numerous advantages. Different embodiments or implementations may yield one or more of the following advantages. It should be noted that this is not an exhaustive list and there may be other advantages which are not described herein. For example, one advantage of the teaching of this application is that accidental key presses are avoided while still allowing fast input through remotely located keys.

Another exemplary advantage of the teaching of the present application is that the method and implementation described does not require expensive and time and computation requiring actions to determine whether a key press is accidental or not.

Although the teaching of the present application has been described in detail for purpose of illustration, it is understood that such detail is solely for that purpose, and variations can be made therein by those skilled in the art without departing from the scope of the teaching of this application.

For example, although the teaching of the present application has been described in terms of a mobile phone, it should be appreciated that the teachings of the present application may also be applied to other types of electronic devices, such as music players, palmtop computers and the like. It should also be noted that there are many alternative ways of implementing the methods and apparatuses of the teachings of the present application.

Features described in the preceding description may be used in combinations other than the combinations explicitly described.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

The term “comprising” as used in the claims does not exclude other elements or steps. The term “a” or “an” as used in the claims does not exclude a plurality. A unit or other means may fulfill the functions of several units or means recited in the claims.

1. A module for avoiding accidental key presses configured to detect a key press on a first key and to temporarily deactivate a second key being adjacent to said first key.

2. A module according to claim 1 further configured to generate key input data corresponding to said first key.

3. A module according to claim 1 further configured to detect a release of said first key and to reactivate said second key upon said release.

4. A module according to claim 1 further configured to detect whether a time period since the detected key press has lapsed or not and reactivate said second key as said time period has lapsed.

5. A module according to claim 1 further configured to detect a release of said second key and to reactivate said second key upon said release.

6. A module according to claim 1 comprising a keypad.

7. A module according to claim 1 comprising logic circuitry for deactivating or reactivating said second key.

8. A device incorporating or configured to incorporate a module according to claim 1.

9. A user interface incorporating or configured to incorporate a module according to claim 1.

10. A user interface according to claim 9 further configured to execute a first and a second application, wherein said user interface is configured to detect a key press on a first key and to temporarily deactivate a second key being adjacent to said first key when executing said first application.

11. A user interface according to claim 10 wherein said first application comprises an input field and wherein said user interface is configured to detect a key press on a first key and to temporarily deactivate a second key being adjacent to said first key when said input field is active.

12. A device incorporating or configured to incorporate a user interface according to claim 9.

13. A computer readable medium including at least computer program code for controlling a user interface comprising a keypad, said computer readable medium comprising software code for detecting a key press of a first key and software code for deactivating a second key.

14. A computer readable medium as in claim 13 further comprising software code for generating key input data corresponding to said first key.

15. A computer readable medium as in claim 13 further comprising software code for detecting a release of said first key and for reactivating said second key upon said release.

16. A computer readable medium as in claim 13 further comprising software code for detecting whether a time period since the detected key press has lapsed or not and reactivating said second key as said time period has lapsed.

17. A computer readable medium as in claim 13 further comprising software code for detecting a release of said second key and to for reactivating said second key upon said release.

18. A device incorporating and implementing a computer readable medium according to claim 13.

19. A device for avoiding accidental key presses comprising means for detecting a key press on a first key and means for temporarily deactivating a second key being adjacent to said first key.

20. A device according to claim 19 further comprising means for generating key input data corresponding to said first key.

21. A device according to claim 19 further comprising means for detecting a release of said first key and means for reactivating said second key upon said release.

22. A method for avoiding accidental key presses comprising detecting a key press on a first key and temporarily deactivating a second key being adjacent to said first key.

23. A method according to claim 22 further comprising generating key input data corresponding to said first key.

24. A method according to claim 22 further comprising detecting a release of said first key and reactivating said second key upon said release.

25. A method according to claim 22 further comprising detecting whether a time period since the detected key press has lapsed or not and reactivating said second key as said time period has lapsed.

26. A method according to claim 22 further comprising detecting a release of said second key and reactivating said second key upon said release.
